(19) United States
(12) Patent Application Publication
(10) Pub. No.: US 2026/0247679 A1
(43) Pub. Date: Aug. 20, 2026

(54) HEMT DEVICES WITH LOW-RESISTANCE OHMIC CONTACTS VIA BARRIER REGROWTH

(71) Applicant: The Regents of the University of Michigan, Ann Arbor, MI (US)

(72) Inventors: Md Tanvir Hasan, Ann Arbor, MI (US); Zetian Mi, Ann Arbor, MI (US)

(21) Appl. No.: 19/545,772

(22) Filed: Feb. 20, 2026

Related U.S. Application Data
(60) Provisional application No. 63/761,001, filed on Feb. 20, 2025.

(51) Int. Cl. H10D 64/01; H10D 30/01; H10D 30/47; H10D 62/85; H10D 64/62

(52) U.S. Cl. CPC H10D 64/0116; H10D 30/015; H10D 30/475; H10D 62/8503; H10D 64/62

(57) ABSTRACT

A method for fabricating a transistor device includes forming a heterostructure including a III-nitride channel layer and a III-nitride semiconductor layer supported by the III-nitride channel layer, removing a portion of the III-nitride semiconductor layer in a channel region of the transistor device, the portion being disposed between source/drain regions in the III-nitride semiconductor layer, and growing a barrier layer in the channel region where the III-nitride semiconductor layer has been removed.

### CROSS-REFERENCE TO RELATED APPLICATION

This application claims the benefit of U.S. provisional application entitled “HEMT Devices with Low-Resistance Ohmic Contacts via Barrier Regrowth,” filed Feb. 20, 2025, and assigned Ser. No. 63/761,001, the entire disclosure of which is hereby expressly incorporated by reference.

### BACKGROUND OF THE DISCLOSURE

### Field of the Disclosure

The disclosure relates generally to III-nitride-based high electron mobility transistor (HEMT) devices.

### Brief Description of Related Technology

Ultra-wide bandgap (UWBG) III-nitride semiconductors, with high breakdown fields and saturation velocities, are ideal for mm-wave and terahertz electronics, enabling efficient, high-gain power amplifiers, and high-temperature electronic applications. Among these, Al-rich AlGaN-channel HEMT devices have emerged as a promising architecture for achieving superior performance in high-power and high-temperature environments due to their enhanced thermal conductivity and electron transport properties. Al-rich AlGaN (>50% Al) offers an estimated higher breakdown field (>10 MV/cm) and saturation velocity (>1.5×10⁷ cm/s), promising greater power gain and density than GaN. A higher breakdown field results in a significantly elevated Baliga figure of merit (BFOM), even though AlGaN alloys exhibit lower electron mobility compared to GaN.

Several practical challenges, such as poor ohmic contacts, lack of matching dielectric materials, and current collapse due to material defects and interface quality, have prevented Al-rich transistors from realizing their full potential. Achieving low-resistance ohmic contacts in Al-rich AlGaN transistors remains a significant challenge due to high resistance and Schottky-like behavior caused by lower electron affinity, which restricts current flow and reduces output power.

Several approaches have been explored to improve the ohmic contacts of Al-rich transistors, including planar, Si-implanted, high-doped GaN or AlGaN regrowth, and reverse graded layers. Different approaches to forming low-resistance ohmic contacts have been explored, but controlling the source/drain regions using these approaches has remained challenging. For instance, the need for precise etching control for regrowth and reverse graded layer approaches has been problematic, as sidewall damage during the etching process leads to high contact resistance.

### SUMMARY OF THE DISCLOSURE

In accordance with one aspect of the disclosure, a method for fabricating a transistor device includes forming a heterostructure including a III-nitride channel layer and a III-nitride semiconductor layer supported by the III-nitride channel layer, removing a portion of the III-nitride semiconductor layer in a channel region of the transistor device, the portion being disposed between source/drain regions in the III-nitride semiconductor layer, and growing a barrier layer in the channel region where the III-nitride semiconductor layer has been removed.

In accordance with another aspect of the disclosure, a transistor device includes a substrate and a heterostructure supported by the substrate, the heterostructure including a III-nitride channel layer, a III-nitride source/drain layer supported by the III-nitride channel layer, the III-nitride source/drain layer being patterned to define source/drain regions, and a III-nitride barrier layer supported by the III-nitride channel layer, the III-nitride barrier layer being disposed in a channel region between the source/drain regions of the III-nitride source/drain layer. The III-nitride channel layer, the III-nitride barrier layer, or both the III-nitride channel layer and the III-nitride barrier layer include an Al-rich III-nitride semiconductor. The heterostructure further includes a III-nitride spacer layer disposed between the III-nitride channel layer and the III-nitride barrier layer.

In connection with any one of the aforementioned aspects, the devices and/or methods described herein may alternatively or additionally include or involve any combination of one or more of the following aspects or features. Forming the heterostructure includes growing an etch stop layer between the III-nitride channel layer and the III-nitride semiconductor layer. The etch stop layer includes AlN. Removing the portion of the III-nitride semiconductor layer includes implementing a dry etch of the III-nitride semiconductor layer. Removing the portion of the III-nitride semiconductor layer includes implementing a thermal decomposition process to remove the III-nitride semiconductor layer remaining in the channel region after the dry etch. The thermal decomposition process is implemented in a growth chamber in which the barrier layer is grown. The III-nitride channel layer includes Al-rich AlGaN. The barrier layer includes an Al-rich III-nitride semiconductor. The barrier layer includes ScAlN. Removing the portion of the III-nitride semiconductor layer includes depositing and patterning a hard mask on the III-nitride semiconductor layer. The method further includes forming a cap layer on the barrier layer, removing the patterned hard mask after growing the cap layer, and depositing ohmic metal stacks on the source/drain regions after removing the patterned hard mask. The III-nitride semiconductor layer includes n-type doped graded AlGaN. The method further includes annealing the ohmic metal stacks. The cap layer includes GaN. The III-nitride semiconductor layer includes n-type doped GaN. The III-nitride spacer layer is disposed between the III-nitride source/drain layer and the III-nitride channel layer. The III-nitride spacer layer includes AlN. The transistor device further includes a cap layer supported by the III-nitride barrier layer. The III-nitride source/drain layer includes n-type doped GaN. The III-nitride source/drain layer includes n-type doped graded AlGaN.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 is a schematic, sectional view of an epitaxial structure or heterostructure configured for barrier regrowth in accordance with one example.

FIG. 2 is a schematic, sectional view of the heterostructure of FIG. 1 after deposition of a hard mask during a fabrication method having barrier regrowth in accordance with one example.

FIG. 3 is a schematic, sectional view of the heterostructure of FIG. 2 after (a) a dry etch procedure of the fabrication method to pattern the hard mask, and (b) a dry etch procedure of the fabrication method to remove the III-nitride semiconductor layer in a channel region, in accordance with one example.

FIG. 4 is a schematic, sectional view of the heterostructure of FIG. 3 after (a) a thermal decomposition procedure of the fabrication method to further remove the III-nitride semiconductor layer in the channel region, and (b) growth of a barrier layer and a cap layer in the channel region, in accordance with one example.

FIG. 5 is a schematic, sectional view of the heterostructure of FIG. 4 after (a) an etch procedure of the fabrication method to remove the hard mask, and (b) deposition of an ohmic metal stack, in accordance with one example.

FIG. 6 is a schematic, sectional view of the heterostructure of FIG. 5 after (a) an anneal procedure of the fabrication method, and (b) deposition of a gate metal stack, in accordance with one example.

FIG. 7 is a schematic, sectional view of a transistor device having an Al-rich III-nitride channel layer and/or an Al-rich III-nitride barrier layer, and a III-nitride spacer layer, in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Methods of fabricating transistor devices involving a regrown barrier layer are described. Regrowth of the barrier layer is achieved without disrupting source/drain contact regions of the transistor device. As a result, low-resistance ohmic contacts with the source/drain contact regions can be realized despite the use of Al-rich semiconductors. Examples of transistor devices having one or more layers (e.g., a channel layer and/or a barrier layer) composed of Al-rich semiconductors are also described.

The barrier layer regrowth of the disclosed methods enables precise control of contact resistance in devices having various Al content levels. Moreover, polarization and band discontinuity can be tuned by adjusting the Al composition of the barrier layer, resulting in higher sheet carrier density and mobility, which may be useful in connection with high-power, high-frequency, and high-temperature device applications.

The terms “regrow” and its derivatives are used herein in connection with the growth of a layer in a region of an epilayer structure or other heterostructure after the removal of one or more layers from the region. The composition and/or other characteristics of the removed portions of the heterostructure may differ from the layer being regrown. Consequently, the terms should therefore not be understood to refer to a second growth of the removed layer(s).

Example methods of fabricating HEMT devices are described below. Regrowth of the barrier layer of the HEMT devices in accordance with the disclosed methods allows low-resistance ohmic contacts to be realized.

Further details regarding the integration of III-nitride alloys into III-nitride-based heterostructures of HEMT devices are set forth in WO 2023/022768 (“Epitaxial Nitride Ferroelectronics”), WO 2023/167709 (“Semiconductor Heterostructures with Scandium III-Nitride Layer”), WO 2023/164071 (“Epitaxial Nitride Ferroelectronic Devices”), and WO 2024/148361 (“Epitaxial Nitride Ferroelectronic Devices”), the entire disclosures of which are hereby incorporated by reference. The disclosed transistor devices may have one or more layers, structures, or other elements or aspects in common with the devices described in the above-referenced patent publications.

Although described in connection with examples of epitaxially grown ScₓAl₁₋ₓN layers, the disclosed methods and devices may be applied to a wide variety of III-nitride based alloys. The disclosed methods and devices may thus include or involve the incorporation of scandium or other rare earth elements into other III-nitride wurtzite structures. For instance, the disclosed methods and devices may include or involve one or more epitaxially grown ScₓAl_{y}Ga_{1-x-y}N layers, ScₓGa₁₋ₓN layers, ScₓIn₁₋ₓN layers, YₓAl₁₋ₓN layers, YₓGa₁₋ₓN layers, BₓAl₁₋ₓN layers BₓGa₁₋ₓN layers, or AlₓGa_{y}In_{1-x-y}BO₃ layers. The configuration, construction, fabrication, and other characteristics of the heterostructures may also vary from the examples described. For instance, the heterostructures may include additional or alternative epitaxially grown layers of ferroelectric and non-ferroelectric nature. The disclosed methods and devices are not limited to III-nitride alloys including scandium. For instance, the III-nitride alloys may include additional or alternative group IIIB elements, such as yttrium (Y) and lanthanum (La).

Although described in connection with examples having heterostructures with solely III-nitride-based layers, the disclosed methods and devices may involve or include one or more layers (e.g., a buffer layer) composed of other semiconductor materials, such as GaAs, InP, and alloys thereof. Still other types of materials may alternatively or additionally be used in the heterostructures, including, for instance, two-dimensional transition metal dichalcogenides, oxide materials (e.g., gallium oxide or gallium oxide-based materials), diamond, silicon carbide, and silicon.

Although some aspects of the disclosed methods are described in connection with MBE growth procedures, additional or alternative non-sputtered epitaxial growth procedures may be used. For instance, metal-organic chemical vapor deposition (MOCVD) and hydride vapor phase epitaxy (HVPE) growth procedures may be used. Still other procedures may be used, including, for instance, pulsed laser deposition procedures.

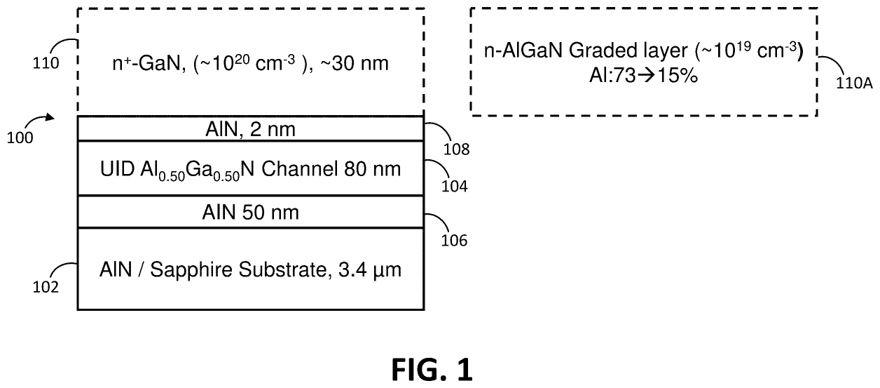

FIG. 1 depicts an epilayer structure or heterostructure 100 formed (e.g., grown) and/or otherwise configured for barrier regrowth in accordance with one example. The epilayer structure 100 may be formed via any growth technique, including, for instance, MOVCD or MBE. In this example, the epilayer structure 100 is formed on, and supported by, a AlN/sapphire substrate 102. The epilayer structure 100 may be grown on other substrates, including, for instance, SiC, single-crystal AlN, and GaN.

The epilayer structure 100 may have one or more III-nitride layers with Al compositions selected in accordance with transistor device application. In this example, the epilayer structure 100 includes a III-nitride channel layer 104 having an Al composition of 50%, but higher Al compositions (e.g., Al-rich compositions) may be used.

In the example of FIG. 1, the epilayer structure 100 includes an AlN layer 106 supported by the substrate 102 that functions as a buffer layer, serving as a back barrier to improve carrier confinement within the channel layer 104 and minimize buffer leakage current. In other cases, the buffer layer 106 may be composed of, or otherwise include, high Al-content AlGaN.

The III-nitride channel layer 104 may be an undoped (UID) AlₓGa₁₋ₓN channel layer supported by the buffer layer 106. In some cases, the Al composition of the III-nitride channel layer 104 may range from an ultra-wide bandgap (x>about 0.40) to an extreme bandgap (x>about 0.60).

To further enhance performance, the epilayer structure or heterostructure 100 may include an AlN spacer layer 108 (e.g., about 1 to about 3 nm thick) supported by the channel layer 104. The spacer layer 108 helps reduce alloy scattering by physically separating the two-dimensional electron gas (2DEG) from the Al-rich AlGaN barrier/channel interface. Additionally, the AlN spacer layer 108 acts as a shield against impurities and ionized dopant scattering originating from the AlGaN barrier layer. As a result, the 2DEG mobility is improved, and sheet resistance is lowered, leading to enhanced device efficiency, particularly in high-power applications and high-voltage operation.

The epilayer structure or heterostructure 100 includes a source/drain layer 110 denoted in a dashed box. Two options are depicted in FIG. 1. In the first option, the source/drain layer 110 is composed of, or otherwise includes, a n-type doped GaN layer (as shown on the left). For instance, the source/drain layer 110 may be heavily n-doped GaN (e.g., about 10²⁰ cm⁻³). In the second option (denoted as 110A), the source/drain layer 110A may be composed of, or otherwise include, a n-type doped graded AlGaN layer (as shown on the right). For instance, the source/drain layer 110A may be composed of an n-doped Al_{y}Ga_{1-y}N graded layer (e.g., about 10¹⁹ cm⁻³). In the example of FIG. 1, the graded AlGaN layer 110A transitions from a high-Al content level (e.g., 73%) to a low-Al content level (e.g., 15%) as shown. The composition of the graded AlGaN layer 110A may decrease from a higher value down to y≤about 0.20. The initial higher composition depends on the Al content in the regrown Al_{z}Ga_{1-z}N barrier. The difference between the barrier composition (z) and channel composition (x) may be maintained at ≥about 20% (z−x≥0.20) to enhance carrier confinement in the channel by optimizing the band discontinuity between the barrier and channel. In some cases, the higher composition of the graded n-Al_{y}Ga_{1-y}N layer 110A is set equal to the composition of the regrown Al_{z}Ga_{1-z}N barrier, meaning high y=z. Subsequently, Ohmic metal stacks are deposited on the highly doped n-GaN layer 110 or the graded n-Al_{y}Ga_{1-y}N layer 110A.

The source/drain layer 110, 110A may be grown in-situ along with the other layers of the epitaxial structure 100. Such in-situ growth enhances the 2DEG/regrown heavily n-doped GaN contact layer interface and mitigates dry etching-induced sidewall damage in the regrown contact layer.

The disclosed methods differ from techniques in which a reverse-graded n-doped Al_{y}Ga_{1-y}N layer is grown on an Al_{z}Ga_{1-z}N barrier and then etched before depositing a Schottky gate metal stack. Such techniques rely on high-precision dry etching; otherwise, the 2DEG may be depleted due to excessive removal of the barrier layer. Although such techniques can reduce contact resistance, the techniques increase gate leakage current due to etching-induced roughness on the barrier surface. Additionally, plasma-induced damage during etching may degrade the electrostatic control of the gate, further affecting device reliability.

In some cases, the method includes a number of cleaning or other procedures in preparation for subsequent processing of the heterostructure. For instance, the epitaxial structure or heterostructure 100 may be cleaned with a solvent clean. In one example, the solvent clean involves or includes Remover PG (10 minutes), IPA (5 minutes), Acetone (10 minutes), and/or IPA (10 minutes) at 80° C. with sonication power set at 10. The cleaning procedures may additionally or alternatively include a cleaning process with DI water. The water cleaning may be repeated a number of times (e.g., at least 5 times).

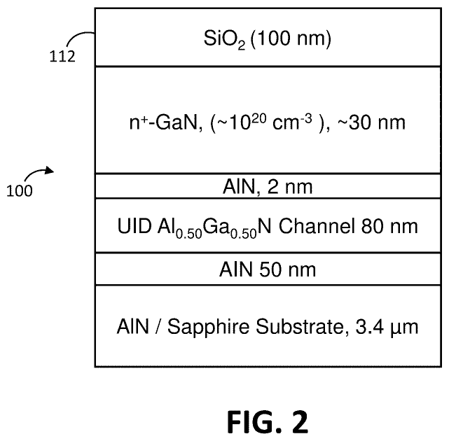

FIG. 2 depicts the heterostructure 100 after deposition of a hard mask 112. The hard mask 112 is deposited to define source/drain regions. In this example, the hard mask 112 is composed of, or otherwise includes, SiO₂. Alternative or additional materials may be used. The hard mask 112 may be deposited using, for instance, PECVD. The thickness of the hard mask 112 may be about 100 nm, but other thicknesses may be used.

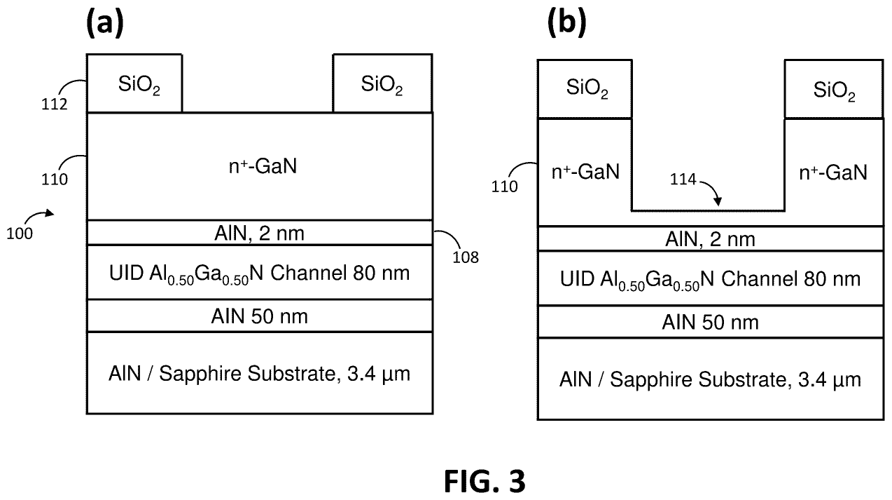

FIG. 3 depicts the removal of a portion of the source/drain III-nitride layer 110 in preparation for the regrowth of a barrier layer configured to induce 2DEG in the channel layer. The removal process may include multiple steps. For instance, as shown in FIG. 3, part (a), the hard mask 112 is etched. Then, as shown in FIG. 3, part (b), the III-nitride semiconductor material of the source/drain layer 110 is etched. The etching of the source/drain layer 110 may be stopped to ensure a small amount or portion 114 (e.g., about 2 to about 3 nm) of the source/drain layer 110 remains.

Various dry etch procedures may be used. For instance, the SiO₂ of the hard mask 112 may be etched using fluorine-based gases (SF₆ and C₄F₈) with helium and argon, while the III-nitride material of the source/drain layer 110 may be etched using chlorine-based gases (BCl₃ and Cl₂).

The AlN layer 108 of the heterostructure 100 acts as an etch stop while also serving as a spacer to prevent impurity incorporation. The AlN spacer layer 108 may thus enhance both 2DEG mobility and sheet density. Moreover, sidewall damage is not a concern in this process because the AlN spacer layer 108 is not patterned.

The use of AlN is useful for a number of reasons. For instance, AlN provides strong polarization effects. AlN has a high spontaneous and piezoelectric polarization, leading to an increased 2DEG density. AlN also reduces alloy scattering. The AlN spacer layer 108 physically separates the 2DEG from the rough AlGaN/GaN interface, reducing alloy disorder scattering. AlN also enhances carrier mobility: By minimizing interface roughness scattering, the AlN spacer layer 108 increases electron mobility, leading to lower sheet resistance. AlN also provides a useful bandgap advantage. AlN has a wide bandgap (6.2 eV), which provides useful carrier confinement, preventing electron spillover into the buffer. AlN also provides thermal stability. The high thermal conductivity (about 3.2 W/cm·K) of AlN improves heat dissipation, which is useful for high-power operation. Notwithstanding the foregoing features, the spacer layer 108 may be composed of, or otherwise include, alternative or additional materials, including, for instance, Al-rich AlGaN, InAlN, and GaN.

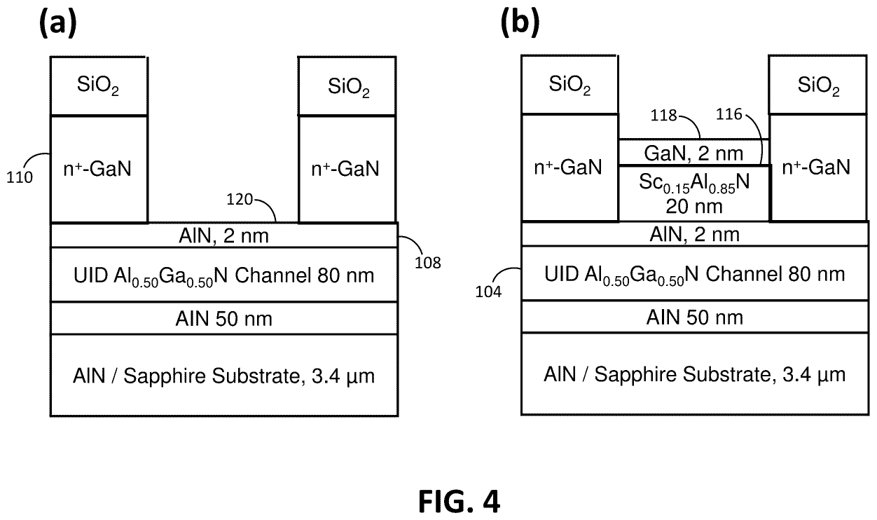

FIG. 4, part (a) depicts thermal decomposition of the portion 114 (e.g., about 2 to about 3 nm) of the source/drain layer 110 remaining after the dry etch (see FIG. 3, part (b)). FIG. 4, part (b), depicts regrowth of a barrier layer 116 along with a cap layer 118. After regrowth of the barrier layer 116, a two-dimensional electron gas (2DEG) density is generated in the channel layer 104 to support operation of the HEMT device.

The thermal decomposition of the portion 114 of the source/drain layer 110 may be implemented in a growth chamber (e.g., an MBE chamber) in which the barrier layer 116 is grown. The heterostructure 100 may thus not be exposed to the ambient between the thermal decomposition and barrier layer growth steps.

The thermal decomposition step may be configured to expose a pristine surface 120 of the spacer layer 108. In the example shown, the thermal decomposition step exposes a pristine AlN surface.

In this example, the barrier layer 116 is composed of, or otherwise includes, ScAlN. The barrier layer 116 may or may not have an Al-rich composition. Alternative or additional III-nitride materials may be used, including, for instance, Al-rich AlGaN and alloys thereof. The difference between the Al content of the barrier layer 116 and the channel layer 104, i.e., the barrier composition (z) and the channel composition (x), may be maintained at ≥about 20% (i.e., z−x≥0.20) to enhance carrier confinement in the channel by optimizing the band discontinuity between the barrier and channel.

In this example, the cap layer 118 is composed of, or otherwise includes, GaN. Alternative or additional III-nitride materials may be used, including, for instance, a variety of other III-nitride materials. The cap layer 118 may have a thickness of about 2 nm, but the thickness may vary.

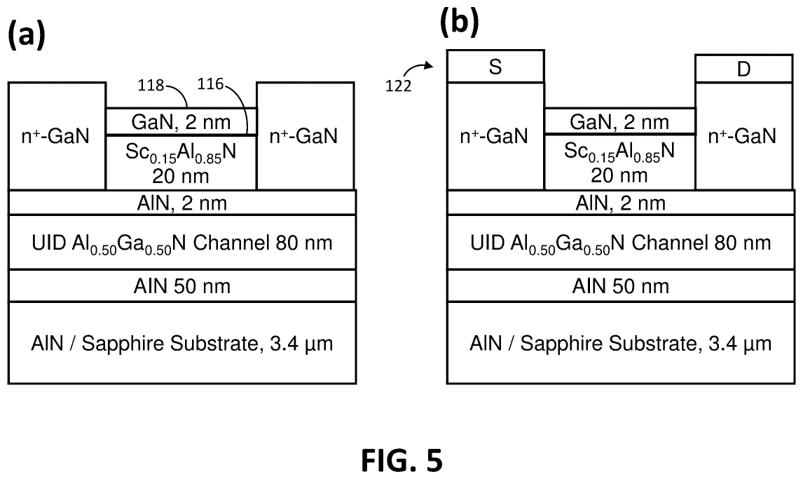

FIG. 5 depicts a number of acts directed to deposition of ohmic metal stacks 122 of the device. As shown in FIG. 5, part (a), the hard mask 112 (FIG. 3) is removed via, e.g., a wet etch procedure. For instance, the SiO₂ hard mask 112 may be removed using wet etching with, e.g., HF. The GaN cap layer 118 protects the surface of the barrier layer 116 during this process.

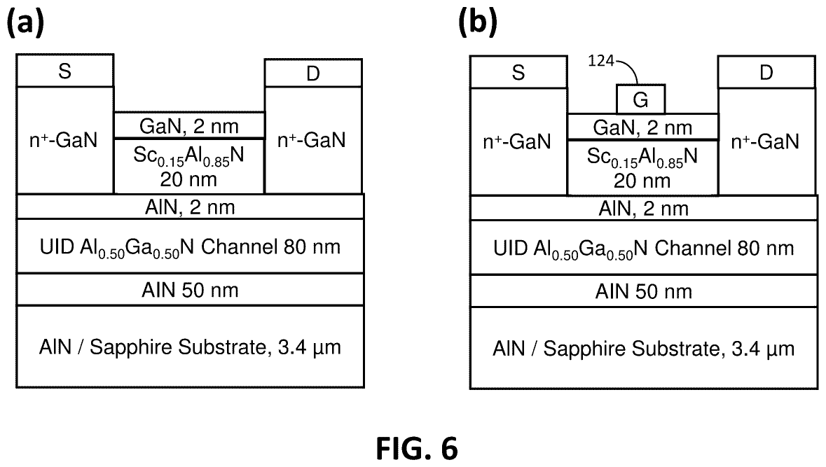

After cleaning and removal of the SiO₂ hard mask 112, the ohmic metal stacks 122 are deposited as shown in FIG. 5, part (b). If the source and drain regions are composed of a n-type doped graded AlGaN (see, e.g., FIG. 1), an anneal procedure (e.g., rapid thermal annealing (RTA)) may be implemented to further improve contact resistance. The gate metal of a gate 124 may then be subsequently deposited as shown in FIG. 6.

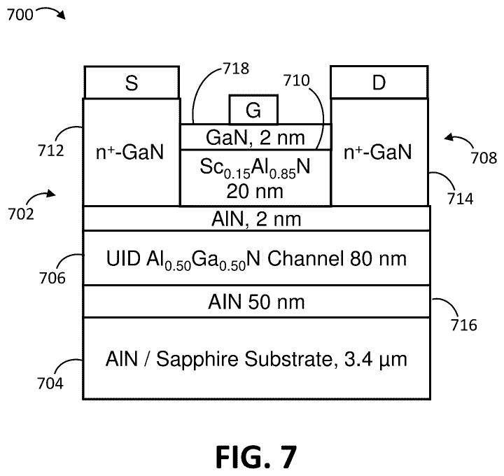

If the source and drain regions are composed of n⁺-doped GaN, the method may not include an annealing procedure. In such cases, the contact metals for both the source/drain contacts and the gate may be deposited simultaneously as shown in FIG. 7, thereby reducing processing costs.

The above-described example methods include a regrown barrier layer to address the challenges of realizing high-resistivity ohmic contacts. The disclosed methods are capable of supporting any combination of high Al-content barrier and channel layers. HEMT devices may thus be realized for a wide variety of high-power, high-frequency, and high-temperature applications. Furthermore, the disclosed methods avoid the challenges arising from etch-induced sidewall damage.

FIG. 7 shows a transistor device 700 having a III-nitride-based heterostructure 702 in accordance with one example. The transistor device 700 may be configured as a HEMT device. The transistor device 700 may be fabricated via one of the example methods described herein, and/or another method. The transistor device 700 may accordingly include a regrown barrier layer as described herein.

As shown in FIG. 7, the transistor device 700 includes a substrate 704. The heterostructure 702 is supported by the substrate 704. The substrate 704 may be an AlN/sapphire composite substrate as shown, or be composed of, or otherwise include, the alternative materials described herein.

As shown in FIG. 7, the heterostructure 702 includes a III-nitride channel layer 706 and a III-nitride source/drain layer 708 supported by the III-nitride channel layer 706. The III-nitride source/drain layer 708 is patterned to define source/drain regions as described herein. The heterostructure 702 further includes a III-nitride barrier layer 710 supported by the III-nitride channel layer 706. The III-nitride barrier layer 710 is disposed in a channel region between source/drain regions 712, 714 of the III-nitride source/drain layer 708. As described herein, the III-nitride channel layer 706 and/or the III-nitride barrier layer 710 are composed of, or otherwise include, an Al-rich III-nitride semiconductor. As also described herein, the III-nitride source/drain layer 708 is composed of, or otherwise includes, n-type doped GaN in some cases. In other cases, the III-nitride source/drain layer 708 is composed of, or otherwise includes n-type doped graded AlGaN.

As shown in FIG. 7, the heterostructure 702 may further include a III-nitride spacer layer 716 disposed between the III-nitride channel layer 706 and the III-nitride barrier layer 710. As also shown in FIG. 7, the III-nitride spacer layer 716 may be disposed between the III-nitride source/drain layer 708 and the III-nitride channel layer 706. As described herein, the III-nitride spacer layer 716 may be composed of, or otherwise include, AlN.

As shown in FIG. 7, the heterostructure 702 may further include a cap layer 718 supported by the III-nitride barrier layer 710. As described herein, the cap layer 718 may be composed of, or otherwise include, GaN.

The thicknesses, dopant concentration levels, and other characteristics of the layers depicted in the drawing figures are presented as examples. For instance, the thickness of each layer may be larger or smaller than the examples shown

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A method for fabricating a transistor device, the method comprising:
forming a heterostructure comprising a III-nitride channel layer and a III-nitride semiconductor layer supported by the III-nitride channel layer;
removing a portion of the III-nitride semiconductor layer in a channel region of the transistor device, the portion being disposed between source/drain regions in the III-nitride semiconductor layer; and
growing a barrier layer in the channel region where the III-nitride semiconductor layer has been removed.

2. The method of claim 1, wherein forming the heterostructure comprises growing an etch stop layer between the III-nitride channel layer and the III-nitride semiconductor layer.

3. The method of claim 2, wherein the etch stop layer comprises AlN.

4. The method of claim 2, wherein removing the portion of the III-nitride semiconductor layer comprises implementing a dry etch of the III-nitride semiconductor layer.

5. The method of claim 4, wherein removing the portion of the III-nitride semiconductor layer comprises implementing a thermal decomposition process to remove the III-nitride semiconductor layer remaining in the channel region after the dry etch.

6. The method of claim 5, wherein the thermal decomposition process is implemented in a growth chamber in which the barrier layer is grown.

7. The method of claim 1, wherein the III-nitride channel layer comprises Al-rich AlGaN.

8. The method of claim 1, wherein the barrier layer comprises an Al-rich III-nitride semiconductor.

9. The method of claim 1, wherein the barrier layer comprises ScAlN.

10. The method of claim 1, wherein removing the portion of the III-nitride semiconductor layer comprises depositing and patterning a hard mask on the III-nitride semiconductor layer.

11. The method of claim 10, further comprising:
forming a cap layer on the barrier layer;
removing the patterned hard mask after growing the cap layer; and
depositing ohmic metal stacks on the source/drain regions after removing the patterned hard mask.

12. The method of claim 11, wherein:
the III-nitride semiconductor layer comprises n-type doped graded AlGaN; and
the method further comprises annealing the ohmic metal stacks.

13. The method of claim 11, wherein the cap layer comprises GaN.

14. The method of claim 1, wherein the III-nitride semiconductor layer comprises n-type doped GaN.

15. A transistor device comprising:
a substrate; and
a heterostructure supported by the substrate, the heterostructure comprising:
a III-nitride channel layer;
a III-nitride source/drain layer supported by the III-nitride channel layer, the III-nitride source/drain layer being patterned to define source/drain regions; and
a III-nitride barrier layer supported by the III-nitride channel layer, the III-nitride barrier layer being disposed in a channel region between the source/drain regions of the III-nitride source/drain layer;
wherein:
the III-nitride channel layer, the III-nitride barrier layer, or both the III-nitride channel layer and the III-nitride barrier layer comprise an Al-rich III-nitride semiconductor; and
the heterostructure further comprises a III-nitride spacer layer disposed between the III-nitride channel layer and the III-nitride barrier layer.

16. The transistor device of claim 15, wherein the III-nitride spacer layer is disposed between the III-nitride source/drain layer and the III-nitride channel layer.

17. The transistor device of claim 15, wherein the III-nitride spacer layer comprises AlN.

18. The transistor device of claim 15, further comprising a cap layer supported by the III-nitride barrier layer.

19. The transistor device of claim 15, wherein the III-nitride source/drain layer comprises n-type doped GaN.

20. The transistor device of claim 15, wherein the III-nitride source/drain layer comprises n-type doped graded AlGaN.
